(19) United States
(12) Patent Application Publication
(10) Pub. No.: US 2025/0247953 A1
(43) Pub. Date: Jul. 31, 2025

(54) STRETCHABLE DEVICE

(71) Applicant: Japan Display Inc., Tokyo (JP)

(72) Inventors: Takumi SANO, Tokyo (JP); Masatomo HISHINUMA, Tokyo (JP)

(21) Appl. No.: 19/016,665

(22) Filed: Jan. 10, 2025

(30) Foreign Application Priority Data
Jan. 30, 2024 (JP) 2024-011784

(51) Int. Cl. H05K 1/02

(52) U.S. Cl. CPC H05K 1/0283; H05K 2201/10151

(57) ABSTRACT

According to an aspect, a stretchable device includes
a stretchable board, a sensor layer, and a counter electrode stacked in order. A direction in which the sensor layer is arranged when viewed from the stretchable board is a first stacking direction, and a direction opposite to the first stacking direction is a second stacking direction. The stretchable board includes a resin base material and an array layer stacked in order in the first stacking direction. The array layer includes: a first surface that is in contact with the sensor layer facing the first stacking direction; a recess that is recessed from the first surface in the second stacking direction; and a detection electrode that is arranged in the recess and comes into contact with the sensor layer only when the sensor layer moves in the second stacking direction.

### CROSS-REFERENCE TO RELATED APPLICATION

This application claims the benefit of priority from Japanese Patent Application No. 2024-011784 filed on Jan. 30, 2024, the entire contents of which are incorporated herein by reference.

### BACKGROUND

### 1. Technical Field

The present disclosure relates to a stretchable device.

### 2. Description of the Related Art

A stretchable device includes a stretchable board with excellent elasticity and flexibility. As described in Japanese Patent Application Laid-open Publication No. 2022-158622, a stretchable board includes an array layer including electrical circuits and a resin base material serving as the base material for the array layer. When the stretchable board is seen in plan view, the stretchable board includes bodies arrayed in a matrix (row-column configuration) and hinges that couple the bodies to each other. The hinge has an arc-shaped bend, for example, and meanders and extends between the bodies.

As an example, the electrical circuits included in the array layer includes a force detection circuit described in Japanese Patent Application Laid-open Publication No. 2022-049511 (JP-A-2022-049511). The force detection circuit includes detection electrodes arranged on the surface of the stretchable board (surface of array layer). Besides the force detection circuit, a force detection device described in JP-A-2022-049511 includes a counter electrode facing the detection electrodes and a sensor layer arranged between the detection electrodes and the counter electrode.

In the force detection device described above, the sensor layer is in contact with the detection electrodes in the initial state (state where no force is applied). In other words, a small amount of current flows from the counter electrode to the detection electrodes. Therefore, when determining whether force is applied, the magnitude of the value of the current that flows to the detection electrodes is used as the criterion for determination. When the increase in the value of the current that flows to the detection electrodes is small, it is difficult to determine whether force is applied, and the sensitivity for detecting the presence of force is low.

For the foregoing reasons, there is a need for providing a stretchable device that has higher sensitivity for detecting force.

### SUMMARY

According to an aspect, a stretchable device includes a stretchable board, a sensor layer, and a counter electrode stacked in order. A direction in which the sensor layer is arranged when viewed from the stretchable board is a first stacking direction, and a direction opposite to the first stacking direction is a second stacking direction. The stretchable board includes a resin base material and an array layer stacked in order in the first stacking direction. The array layer includes: a first surface that is in contact with the sensor layer facing the first stacking direction; a recess that is recessed from the first surface in the second stacking direction; and a detection electrode that is arranged in the recess and comes into contact with the sensor layer only when the sensor layer moves in the second stacking direction.

### BRIEF DESCRIPTION OF THE DRAWINGS

FIG. 1 is a perspective view of a stretchable device viewed from a direction facing a surface according to a first embodiment;

FIG. 2 is a schematic view of a section of the stretchable device along a gate line according to the first embodiment;

FIG. 3 is a sectional view viewed from the direction of arrow along line IV-IV of FIG. 4;

FIG. 4 is a plan view of a first surface of a stretchable board viewed from a sensor layer according to the first embodiment;

FIG. 5 is a sectional view of the stretchable device along line V-V of FIG. 4 according to the first embodiment;

FIG. 6 is a diagram of an electrical circuit of a force detection circuit of the stretchable device according to the first embodiment;

FIG. 7 is a sectional view of the stretchable device when force is applied to the surface thereof according to the first embodiment;

FIG. 8 is an enlarged view of a body of the stretchable board viewed from a first stacking direction according to a first modification; and

FIG. 9 is an enlarged view of the body of the stretchable board viewed from the first stacking direction according to a second modification.

### DETAILED DESCRIPTION

Exemplary aspects (embodiments) to embody the present disclosure are described below in greater detail with reference to the accompanying drawings. The contents described in the embodiments below are not intended to limit the invention according to the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present invention and easily conceivable by those skilled in the art naturally fall within the scope of the present invention. To simplify the explanation, the drawings may possibly illustrate the width, the thickness, the shape, and other elements of each unit more schematically than the actual aspect. These elements, however, are given by way of example only and are not intended to limit interpretation of the present invention. In the present specification and the drawings, components similar to those previously described with reference to previous drawings are denoted by like reference numerals, and detailed explanation thereof may be appropriately omitted.

When the term “above” is used to describe an aspect where a first structure is arranged on a second structure in the present specification and the claims, it includes both of the following cases unless otherwise noted: a case where the first structure is arranged on and in contact with the second structure, and a case where the first structure is arranged above the second structure with still another structure interposed therebetween.

### First Embodiment

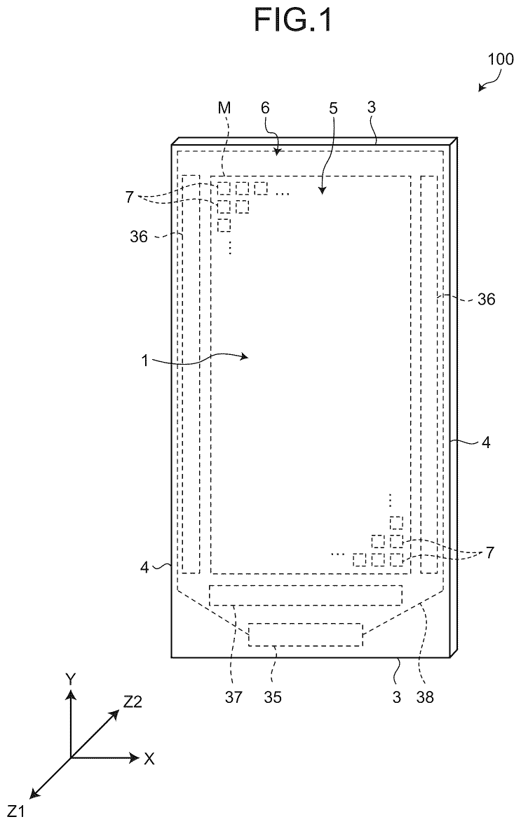

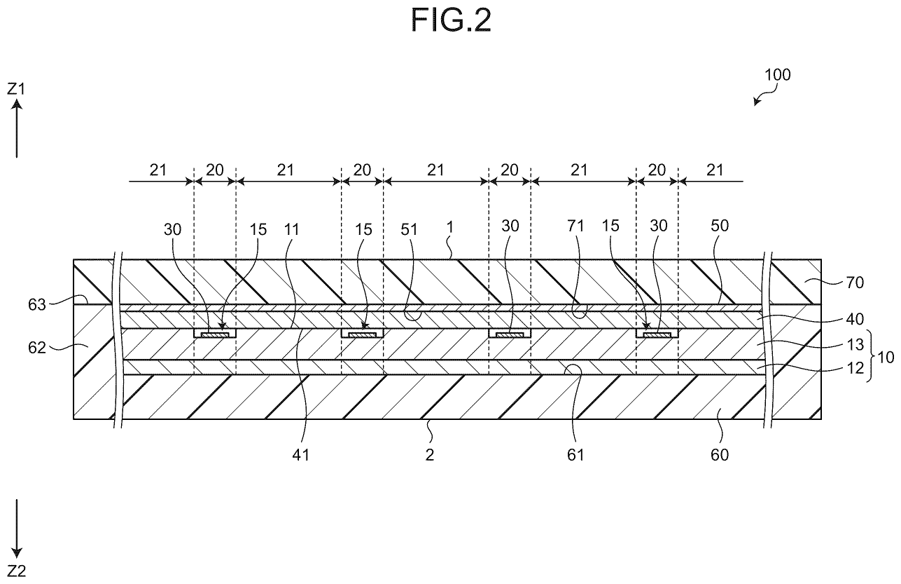

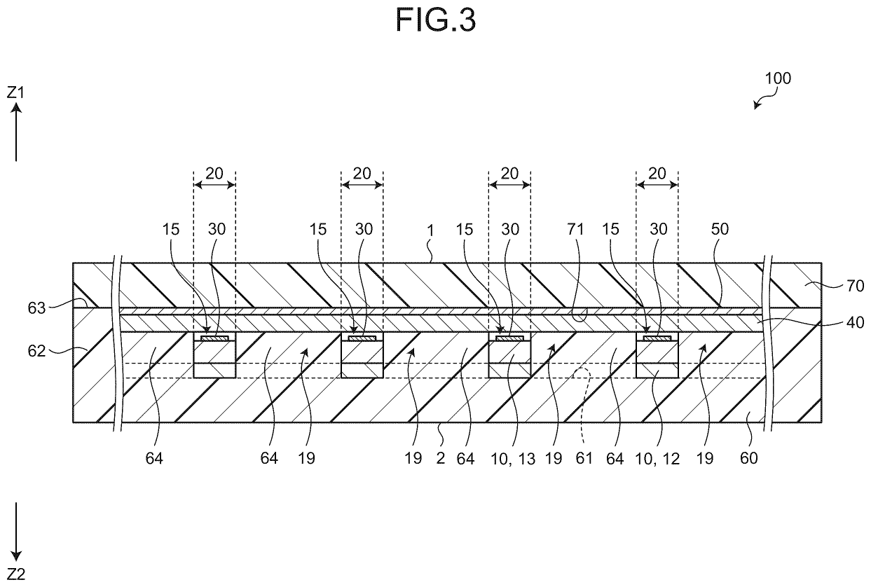

FIG. 1 is a perspective view of a stretchable device viewed from a direction facing a surface according to a first embodiment. As illustrated in FIG. 1, a stretchable device 100 has a flat plate shape. The stretchable device 100 has a surface 1 and a back surface 2 (back surface 2 is not illustrated in FIG. 1, and refer to FIGS. 2 and 3) facing opposite to each other. The surface 1 is a surface on which force can be detected. In the following description, the direction parallel to the surface 1 and the back surface 2 is referred to as a planar direction. A direction intersecting the planar direction is referred to as a stacking direction.

When viewed from the direction facing the surface 1, the stretchable device 100 is divided into a detection region 5 and a frame region 6. A virtual line M illustrated in FIG. 1 indicates the boundary between the detection region 5 and the frame region 6. The detection region 5 is an area where force can be detected. The detection region 5 is positioned at the center of the stretchable device 100 and has a rectangular (quadrilateral) shape when viewed from the direction facing the surface 1. The frame region 6 is an area where force fails to be detected. The frame region 6 is positioned at the ends of the stretchable device 100 and has a frame shape (quadrilateral frame shape).

The detection region 5 is divided into a plurality of individual detection regions 7. In other words, force can be detected in each of the individual detection regions 7. The individual detection regions 7 are arrayed in a first direction X parallel to the planar direction and in a second direction Y parallel to the planar direction and intersecting the first direction X. In the configuration according to the first embodiment, the first direction X is parallel to a short side 3 and the second direction Y is parallel to a long side 4.

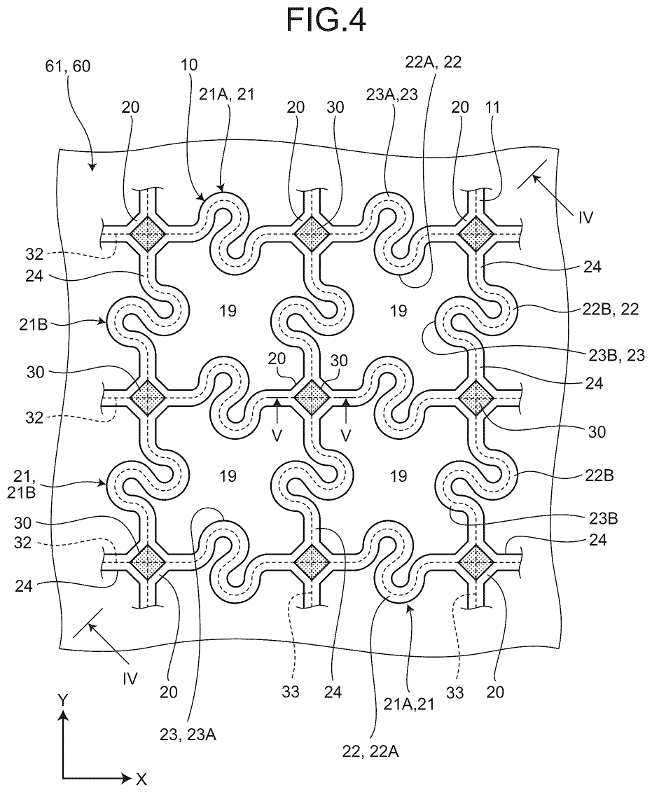

FIG. 2 is schematic of a section of the stretchable device along a gate line according to the first embodiment. FIG. 3 is a sectional view viewed from the direction of arrow along line IV-IV of FIG. 4. As illustrated in FIGS. 2 and 3, the stretchable device 100 includes a first stretchable resin layer 60, a stretchable board 10, a sensor layer 40, a counter electrode 50, and a second stretchable resin layer 70 stacked in order in the stacking direction. In other words, the stretchable board 10, the sensor layer 40, and the counter electrode 50 are sandwiched between a pair of stretchable resin layers (the first stretchable resin layer 60 and the second stretchable resin layer 70).

In the stacking direction, the direction in which the second stretchable resin layer 70 is arranged when viewed from the first stretchable resin layer 60 is hereinafter referred to as a first stacking direction Z1, and the direction opposite to the first stacking direction Z1 is referred to as a second stacking direction Z2.

The first stretchable resin layer 60 and the second stretchable resin layer 70 has insulating, elastic, and flexible properties. The resin used as the first stretchable resin layer 60 and the second stretchable resin layer 70 is acrylic elastomer, for example. The first stretchable resin layer 60 and the second stretchable resin layer 70 according to the present disclosure are not limited to acrylic elastomer. They may be acrylic resin, epoxy resin, urethane resin, or the like and are not particularly limited.

The first stretchable resin layer 60 and the second stretchable resin layer 70 are each formed in a plate shape and extend in the planar direction. The surface of the first stretchable resin layer 60 in the second stacking direction Z2 serves as the back surface 2 of the stretchable device 100. The first stretchable resin layer 60 has a stacking surface 61 facing the first stacking direction Z1 and opposed to the stretchable board 10.

The stretchable board 10 extends in the planar direction along the stacking surface 61. The stretchable board 10 has a first surface 11 facing the first stacking direction. The shape of the stretchable board 10 in plan view will be described later. The stretchable board 10 includes a resin base material 12 stacked on the stacking surface 61 of the first stretchable resin layer 60, and an array layer 13 stacked on the resin base material 12 in the first stacking direction Z1.

The resin base material 12 adheres to the stacking surface 61 of the first stretchable resin layer 60. The resin base material 12 has elastic, flexible, and insulating properties. The resin base material 12 is made of resin material, such as polyimide.

The array layer 13 includes a plurality of insulating layers stacked in the stacking direction and a force detection circuit, which are not specifically illustrated. The force detection circuit will be described later in detail. The insulating layer arranged uppermost in the first stacking direction Z1 out of the insulating layers of the array layer 13 serves as the first surface 11. In other words, the array layer 13 has the first surface 11 that faces the first stacking direction Z1 and is in contact with the sensor layer 40.

The surface of the second stretchable resin layer 70 in the first stacking direction Z1 serves as the surface 1 of the stretchable device 100. The second stretchable resin layer 70 has a counter surface 71 facing the second stacking direction Z2 and opposed to the stretchable board 10.

The counter electrode 50 is bonded to the counter surface 71 of the second stretchable resin layer 70. The counter electrode 50 extends in the planar direction, is made of metal material, and is formed across the individual detection regions 7. The counter electrode 50 is what is called a solid film provided over the entire detection region 5 in plan view. The counter electrode 50 is coupled to common wiring 38 (refer to FIG. 1) by wiring, which is not illustrated. As a result, the counter electrode 50 is supplied with a certain amount of current from a drive IC. The sensor layer 40 is bonded to a surface 51 of the counter electrode 50 facing the second stacking direction Z2.

The sensor layer 40 is made of material containing conductive fine particles in a highly insulating resin layer. The fine particles are dispersed in the resin layer and are separated from each other. Therefore, the resistance of the sensor layer 40 is high when the resin layer is not deformed. By contrast, when the resin layer is compressed, the fine particles come into contact with or proximity to each other, and the resistance of the sensor layer 40 decreases. As the amount of compression of the resin layer increases, the number of fine particles in contact increases, and the resistance of the sensor layer 40 is significantly reduced. The sensor layer 40 is provided over the entire detection region 5 in plan view. A surface 41 of the sensor layer 40 facing the second stacking direction Z2 is in contact with the first surface 11 of the stretchable board 10.

The ends of the first stretchable resin layer 60 are provided with a frame part 62 that protrudes in the first stacking direction Z1 with respect to the stacking surface 61. The frame part 62 has an annular shape in plan view. The stretchable board 10, the sensor layer 40, and the counter electrode 50 are arranged inside the frame part 62. A surface 63 of the frame part 62 in the first stacking direction Z1 is bonded to the counter surface 71 of the second stretchable resin layer 70. Therefore, the first stretchable resin layer 60 and the second stretchable resin layer 70 cooperate to serve as a housing that accommodates the stretchable board 10.

As illustrated in FIG. 3, the stretchable board 10 has a plurality of through holes 19 passing therethrough in the stacking direction. The first stretchable resin layer 60 has a plurality of protrusions 64 protruding from the stacking surface 61 toward the first stacking direction Z1 and fit into the through holes 19.

While the through hole 19 according to the present embodiment is filled with the first stretchable resin layer 60, the through hole 19 according to the present disclosure may be filled with the second stretchable resin layer 70. Alternatively, the through hole 19 may be filled with the first stretchable resin layer 60 and the second stretchable resin layer 70. Still alternatively, the through hole 19 may be filled with resin other than the first stretchable resin layer 60 or the second stretchable resin layer 70. Still alternatively, the through hole 19 may be a space provided with nothing.

FIG. 4 is a plan view of the first surface of the stretchable board viewed from the sensor layer according to the first embodiment. As illustrated in FIG. 4, the stretchable board 10 includes a plurality of bodies 20 and a plurality of hinges 21 meandering and extending in the planar direction.

The bodies 20 are arranged to overlap the respective individual detection regions 7 (refer to FIG. 1) in the stacking direction. Therefore, the bodies 20 are spaced apart from each other in the first direction X and the second direction Y. The body 20 has an octagonal shape in plan view. The shape of the body 20 according to the present disclosure in plan view is not limited to an octagonal shape and may be circular or other polygonal shapes.

The hinge 21 couples the bodies 20 adjacent to each other. The hinges 21 include two kinds of hinges: a first hinge 21A extending in the first direction X, and a second hinge 21B extending in the second direction Y. When the first hinge 21A is rotated by 90 degrees, it has the same shape as that of the second hinge 21B. The part not provided with the bodies 20 or the hinges 21 in the stretchable board 10 serves as the through holes 19 passing through the stretchable board 10 in the stacking direction.

As illustrated in FIG. 3, the through holes 19 are filled with the first stretchable resin layer 60. Therefore, the hinges 21 adjacent to the first stretchable resin layer 60 in the first direction X or the second direction Y have low rigidity. In other words, when a stretching load in the first direction X or the second direction Y is applied, the hinges 21 of the stretchable board 10 are deformed. By contrast, the amount of deformation of the bodies 20 is small because they are more rigid than the hinges 21.

The hinge 21 has two arc-shaped arcs 22 and 23 and meanders due to them. The arcs 22 and 23 in the first hinge 21A are as follows: one is a first arc 22A protruding in one direction of the second direction Y, and the other is a second arc 23A protruding in the other direction of the second direction Y. The arcs 22 and 23 in the second hinge 21B are as follows: one is a first arc 22B protruding in one direction of the first direction X, and the other is a second arc 23B protruding in the other direction of the first direction X.

For example, when a tensile load acts on both ends of the hinge 21, the arcs 22 and 23 deform such that their radii of curvature increase. As a result, the distance between the two bodies 20 coupled to both ends of the hinge 21 increases, and the stretchable board 10 expands.

By contrast, when a compressive load acts on both ends of the hinge 21, the arcs 22 and 23 deform such that their radii of curvature decrease. As a result, the distance between the bodies 20 coupled to both ends of the hinge 21 decreases, and the stretchable board 10 contracts.

Both ends of the hinge 21 each have a linear base 24 coupled to the body 20. While the hinge 21 according to the present embodiment has the arc-shaped arcs 22 and 23, the hinge 21 according to the present disclosure may have L-shaped bends instead of the arcs 22 and 23 and is not limited to the hinge according to the embodiment.

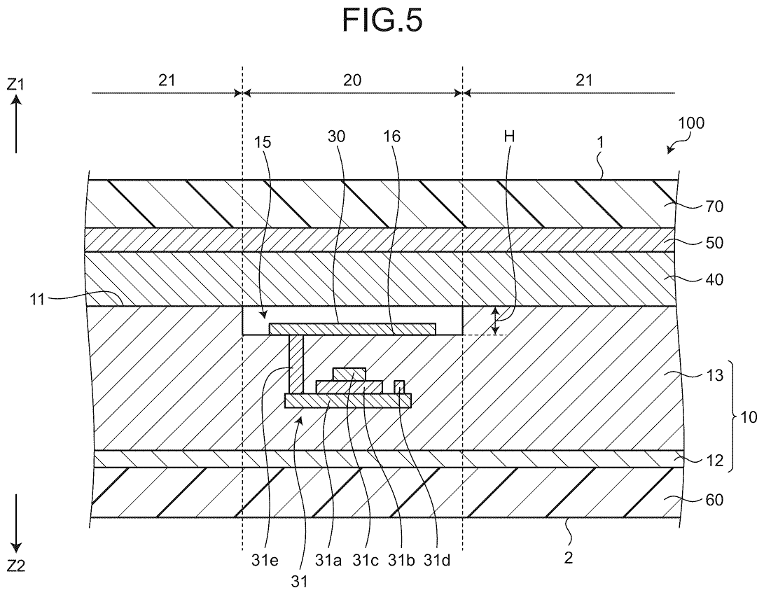

FIG. 5 is a sectional view of the stretchable device along line V-V of FIG. 4 according to the first embodiment. As illustrated in FIG. 5, the first surface 11 of the stretchable board 10 has a recess 15 recessed in the second stacking direction. The recess 15 is formed in the body 20. In other words, the recess 15 is formed in the area overlapping the entire body 20 in plan view. Therefore, the first surface 11 is composed only of the surfaces of the hinges 21 in the first stacking direction. The recess 15 is not illustrated in FIG. 4.

As illustrated in FIG. 4, the stretchable board 10 (array layer 13) includes a plurality of detection electrodes 30 as the components of the force detection circuit. The detection electrodes 30 are provided to the respective bodies 20. In other words, the detection electrodes 30 are provided to the respective individual detection regions 7.

As illustrated in FIG. 5, the detection electrode 30 is arranged on a bottom surface 16 of the recess 15 of the stretchable board 10. The depth H of the recess 15 in the stacking direction is 3 μm to 10 μm, which is larger than the thickness of the detection electrode 30. Therefore, the detection electrode 30 is separated from the sensor layer 40.

As illustrated in FIG. 5, the stretchable board 10 (array layer 13) includes a plurality of drive transistors 31 as the components of the force detection circuit. The drive transistors 31 are provided to the respective bodies 20. Therefore, the detection electrodes 30 are provided to the respective individual detection regions 7. The drive transistor 31 includes a semiconductor layer 31a, a gate insulating film 31b, a gate electrode 31c, a drain electrode 31d, and a source electrode 31e. The source electrode 31e is electrically coupled to the detection electrode 30.

The stretchable board 10 (array layer 13) further includes gate lines 32 (refer to FIG. 4), signal lines 33 (refer to FIG. 4), a coupler 35 (refer to FIG. 1), a gate line drive circuit 36 (refer to FIG. 1), and a signal line selection circuit 37 (refer to FIG. 1) as the components of the force detection circuit.

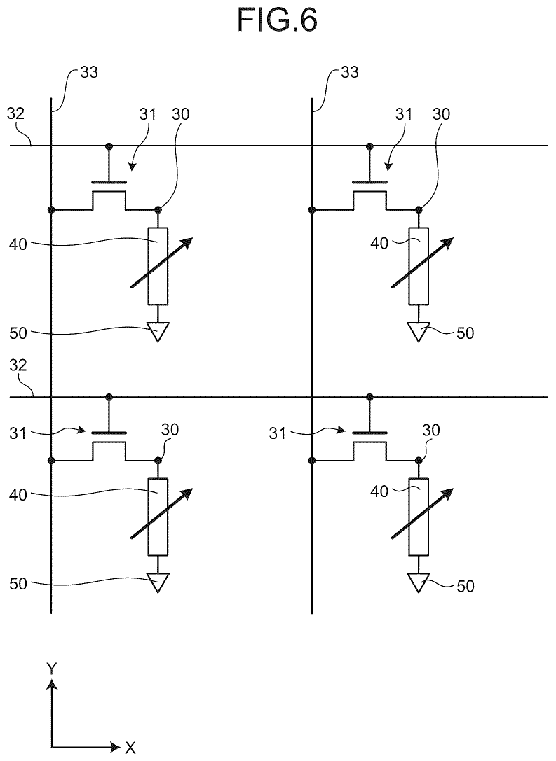

FIG. 6 is a diagram of an electrical circuit of the force detection circuit of the stretchable device according to the first embodiment. As illustrated in FIG. 6, the gate lines 32 extend in the first direction X. The signal lines 33 extend in the second direction Y.

As illustrated in FIG. 4, the gate line 32 is arranged over a plurality of first hinges 21A and a plurality of bodies 20, thereby extending in the first direction X. A plurality of gate lines 32 are arrayed in the second direction Y. The gate line 32 is coupled to the gate electrode 31c of the drive transistor 31 in each body 20. As illustrated in FIG. 6, one gate line 32 is coupled to a plurality of drive transistors 31 arrayed in the first direction X.

The signal line 33 is arranged over a plurality of second hinges 21B and a plurality of bodies 20, thereby extending in the second direction Y. A plurality of signal lines 33 are arrayed in the first direction X. The signal line 33 is coupled to the drain electrode 31d of the drive transistor 31. As illustrated in FIG. 6, one signal line 33 is coupled to a plurality of drive transistors 31 arrayed in the second direction Y.

The coupler 35, the gate line drive circuit 36, and the signal line selection circuit 37 are arranged in the frame region 6 of the array layer 13. The coupler 35 is coupled to a drive integrated circuit (IC) arranged outside the stretchable device 100. The drive IC according to the present disclosure may be mounted as a chip on film (COF) on a flexible printed circuit board or a rigid board coupled to the coupler 35. Alternatively, the drive IC may be mounted as a chip on glass (COG) in the frame region 6.

The gate line drive circuit 36 is a circuit that drives a plurality of gate lines 32 (refer to FIG. 4) based on various control signals supplied from the drive IC. The gate line drive circuit 36 sequentially or simultaneously selects the gate lines 32 and supplies gate drive signals to the selected gate line 32.

The signal line selection circuit 37 is a switch circuit that sequentially or simultaneously selects a plurality of signal lines 33 (refer to FIG. 4). The signal line selection circuit 37 is, for example, a multiplexer. The signal line selection circuit 37 couples the selected signal line 33 to the drive IC based on selection signals supplied from the drive IC. With this configuration, when the gate line 32 is scanned, the detection electrodes 30 and the signal lines 33 are electrically coupled.

Therefore, the electrical signals (current values) input to the detection electrodes 30 are transmitted to the drive IC via the signal lines 33.

As illustrated in FIG. 1, the frame region 6 of the array layer 13 is further provided with the common wiring 38 and wiring for a common electrode (not illustrated). The common wiring 38 is wiring for supplying a predetermined voltage to the counter electrode 50 and extends along the frame region 6. The common wiring 38 is coupled to the drive IC via the coupler 35 and is supplied with a constant voltage from the drive IC.

Next, the advantageous effects of the stretchable device 100 according to the first embodiment are described. As illustrated in FIG. 5, when no force is applied to the surface 1, a gap is formed between the sensor layer 40 and the detection electrode 30, and the sensor layer 40 is not in contact with the detection electrode 30. Therefore, no electrical signal is output from the detection electrode 30 via the signal line 33 (the amount of current is zero).

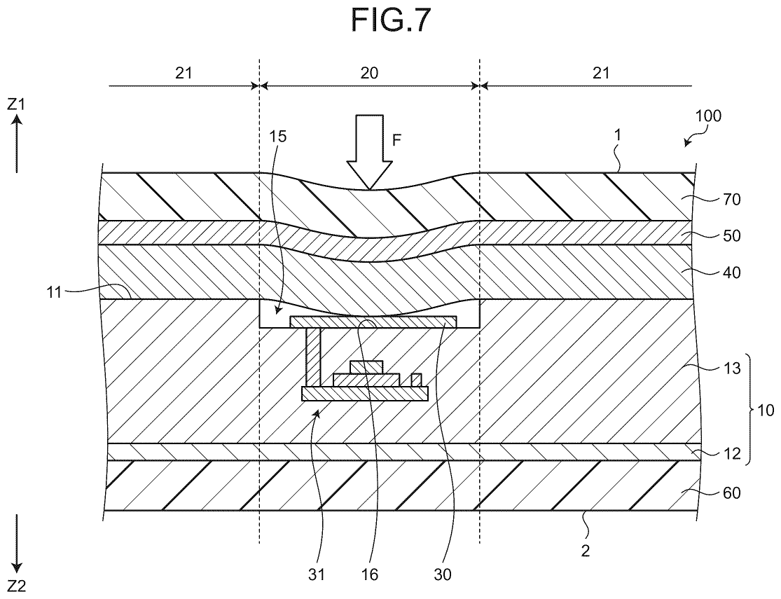

FIG. 7 is a sectional view of the stretchable device when force is applied to the surface thereof according to the first embodiment. As illustrated in FIG. 7, when force F is applied to the surface 1, the second stretchable resin layer, the counter electrode, and the sensor layer are pressed in the second stacking direction. As a result, the sensor layer comes into contact with the detection electrode 30. Therefore, the counter electrode and the detection electrode are electrically coupled via the sensor layer 40, and an electrical signal flows to the detection electrode.

When the force increases, the sensor layer 40 is compressed in the stacking direction between the detection electrode 30 and the counter electrode 50. As a result, the resistance of the sensor layer decreases, and the electrical signal (current value) flowing to the detection electrode increases.

In the stretchable device 100 according to the first embodiment described above, the sensor layer 40 and the detection electrode 30 come into contact, and the electrical signal is detected only when the sensor layer 40 moves in the second stacking direction Z2 (when force is applied). In other words, whether force is applied can be readily determined to have higher sensitivity for detecting force.

Thus, the first embodiment has been described above. Next, modifications in which the shape of the recess 15 varies are described.

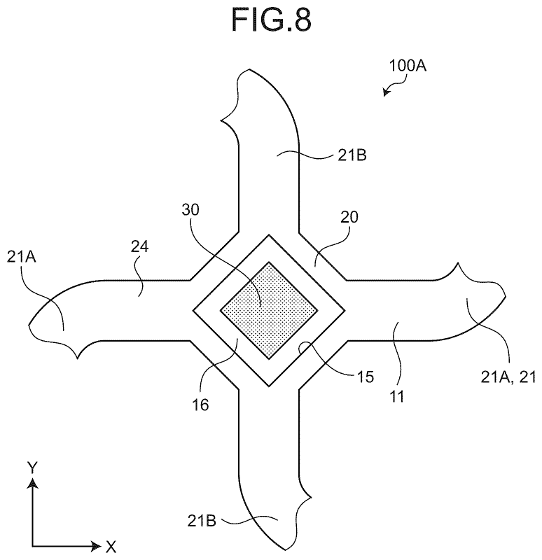

FIG. 8 is an enlarged view of the body of the stretchable board viewed from the first stacking direction according to a first modification. As illustrated in FIG. 8, a recess 15A of a stretchable device 100A according to the first modification is similar to the detection electrode 30 and has a square shape. The recess 15A is smaller than the body. Therefore, the first surface 11 is composed not only of the surfaces of the hinges 21 in the first stacking direction but also of the surfaces of the bodies 20 in the first stacking direction. The present disclosure may be the first modification described above and can achieve the same advantageous effects as the first embodiment.

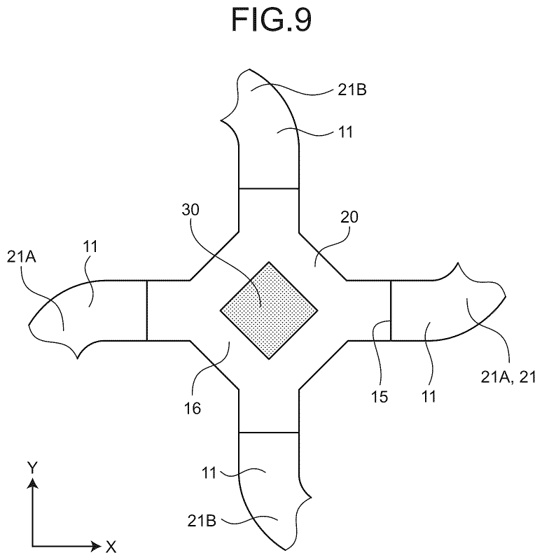

FIG. 9 is an enlarged view of the body of the stretchable board viewed from the first stacking direction according to a second modification. As illustrated in FIG. 9, a recess 15B of a stretchable device 100B according to the second modification extends not only to the body 20 but also to the bases 24 of the hinges 21. While the detection electrode 30 according to the embodiment and the modifications is arranged to overlap only with the body 20, part of the detection electrode 30 may be arranged on the bases 24 if the recess 15B extends to the bases 24 as described in the second modification.

While the embodiment and the modifications have been described above, the present disclosure is not limited to the examples described in the embodiment and the modifications. For example, while the entire surfaces of the hinges 21 in the first stacking direction constitute the first surface 11 according to the first embodiment, part of the surfaces of the hinges 21 in the first stacking direction may be cut out. If part of the surfaces of the bodies 20 in the first stacking direction constitutes the first surface 11 as described in the first modification, the surfaces of the hinges 21 in the first stacking direction may be recessed with respect to the first surface 11.

What is claimed is:

1. A stretchable device comprising:
a stretchable board, a sensor layer, and a counter electrode stacked in order, wherein
a direction in which the sensor layer is arranged when viewed from the stretchable board is a first stacking direction, and a direction opposite to the first stacking direction is a second stacking direction,
the stretchable board comprises a resin base material and an array layer stacked in order in the first stacking direction, and
the array layer comprises:
a first surface that is in contact with the sensor layer facing the first stacking direction;
a recess that is recessed from the first surface in the second stacking direction; and
a detection electrode that is arranged in the recess and comes into contact with the sensor layer only when the sensor layer moves in the second stacking direction.

2. The stretchable device according to claim 1, wherein
the stretchable board further comprises:
bodies that are spaced apart from each other; and
a plurality of hinges that couple the bodies, and
the recess is formed on the first surface of the bodies.

3. The stretchable device according to claim 1, further comprising:
a first stretchable resin layer that is arranged in the second stacking direction with respect to the stretchable board; and
a second stretchable resin layer that is arranged in the first stacking direction with respect to the counter electrode.

4. The stretchable device according to claim 2, further comprising:
a first stretchable resin layer that is arranged in the second stacking direction with respect to the stretchable board; and
a second stretchable resin layer that is arranged in the first stacking direction with respect to the counter electrode.
